(19) United States
(12) Patent Application Publication
(10) Pub. No.: US 2017/0139296 A1
(43) Pub. Date: May 18, 2017

(54) DISPLAY DEVICE AND METHOD FOR MANUFACTURING SAME

(71) Applicant: SHARP KABUSHIKI KAISHA, Sakai City, Osaka (JP)

(72) Inventors: Hidenobu KIMOTO, Sakai City (JP); Tetsuya TARUI, Sakai City (JP); Yoshihiro SEGUCHI, Sakai City (JP); Takehisa SUGIMOTO, Sakai City (JP)

(21) Appl. No.: 15/322,261

(22) PCT Filed: Jul. 23, 2015
(86) PCT No.: PCT/JP2015/070918

§ 371 Date: Dec. 27, 2016

(30) Foreign Application Priority Data
Jul. 30, 2014 (JP) 2014-154720

(51) Int. Cl. G02F 1/1362; G02F 1/1333; H01L 21/768; H01L 21/027; H01L 21/3213; G09G 3/36; H01L 27/12

(52) U.S. Cl. CPC G02F 1/136259; G09G 3/3677; G09G 3/3688; G02F 1/133345; G02F 1/136286; H01L 27/124; H01L 27/1288; H01L 21/0274; H01L 21/32139; H01L 21/32134; H01L 21/32135; H01L 21/76892; G09G 2310/0202; G02F 2001/136295; G02F 2001/13629; G02F 2001/136263

(57) ABSTRACT

A first wiring of the present invention is a wiring having a two-layer structure including a lower layer wiring and an upper layer wiring which is formed to cover an upper surface and both side surfaces of the lower layer wiring, and thus, even if the lower layer wiring includes a part where the line width is reduced and which is nearly disconnected due to a particle or the like attached at the time of formation of the lower layer wiring, the probability is extremely low that a particle is attached again, to the upper layer wiring at the time of formation of the upper layer wiring, at a position corresponding to the nearly disconnected part of the lower layer wiring. Moreover, the lower layer wiring and the upper layer wiring are electrically connected to each other. Accordingly, even if the narrowed part of the lower layer wiring is disconnected, the first wiring is a highly reliable wiring whose conductivity is maintained through the upper layer wiring, and a liquid crystal display device can continuously display an image normally.

### TECHNICAL FIELD

The present invention relates to a display device and a method for manufacturing the same, and more particularly, to a display device including a highly reliable wiring, and a method for manufacturing the same.

### BACKGROUND ART

In recent years, a liquid crystal display device is often mounted on an electronic appliance as a display. However, an image is sometimes not normally displayed on the liquid crystal display device while a user is operating such an electronic appliance. As one cause of occurrence of such a phenomenon, the following is confirmed. That is, a wiring of the liquid crystal display device is formed by etching a metal film that is deposited on an insulating substrate. At the time of deposition of the metal film, particles of about 2 μm to 10 μm are sometimes attached to the surface of the metal film, and a wiring including a part that is susceptible to disconnection may be formed due to such a particle. If an electrical appliance on which a liquid crystal display device including such a wiring is mounted is repeatedly used by a user, and stress such as electrical stress is repeatedly applied to such a part, the wiring will be disconnected at the part.

If presence of a disconnected wiring is found in the manufacturing process of the liquid crystal display device or at the time of inspection before shipping, such a liquid crystal display device may be removed as a defective product. However, even if apart which is susceptible to disconnection is formed, if there is no disconnection, the liquid crystal display device may be determined to be a non-defective product at the time of inspection before shipping, and is possibly shipped. Moreover, Patent Document 1 discloses agate path wiring having a two-layer structure including a first gate path wiring and a second gate path wiring that is stacked on the first gate path wiring.

### PRIOR ART DOCUMENT

### Patent Document

[Patent Document 1] Japanese Patent Application Laid-Open No. H10-213809

### SUMMARY OF THE INVENTION

### Problems to be Solved by the Invention

The gate path wiring disclosed in Patent Document 1 is formed of two metal layers, but a gate pad and a gate electrode which are formed simultaneously with the gate path wiring are each formed of one metal layer. Accordingly, if a part which is susceptible to disconnection is formed in the gate pad or the gate electrode due to a particle attached at the time of deposition of the metal film, the part may be disconnected due to use after shipping or may cause inconvenience, thereby reducing reliability of the wiring.

Furthermore, the gate pad and the gate electrode are formed simultaneously at the time of forming the second gate path wiring. Accordingly, a mask different from a photomask that is used for forming the first gate path wiring has to be used as the photomask to be used for forming the second gate path wiring. In this case, the misregistration between the first gate path wiring and the second gate path wiring has to be within a predetermined range so that the second gate path wiring covers the first gate path wiring. Generally, in the case of causing the misregistration between two patterns to fall within a predetermined range, there are influences from alignment accuracy of an exposure device in a photolithography step, and also, from the misregistration between patterns formed in photomasks and dimensional accuracies of the patterns. As a result, if the number of photomasks to be used is increased, the misregistration between two patterns is increased accordingly. Therefore, with a liquid crystal display device including a gate path wiring formed of two metal layers as disclosed in Patent Document 1, the misregistration between two patterns is great, and there is a problem that the reliability of the wiring is reduced.

Accordingly, an object of the present invention is to provide a display device including a highly reliable wiring, and a method for manufacturing the same.

### Means for Solving the Problems

A first aspect of the present invention is directed to a display device formed on an insulating substrate, the device including:

a display unit including a plurality of scanning signal lines formed on the insulating substrate, a plurality of data signal lines each intersecting with the plurality of scanning signal lines, and a plurality of pixel formation portions arranged in a matrix in correspondence with respective intersections of the scanning signal lines and the data signal lines;

a scanning signal line drive circuit configured to sequentially activate the scanning signal lines;

a data signal line drive circuit configured to apply a voltage according to image data to the data signal line; and

a plurality of types of wirings connected, respectively, to the scanning signal line drive circuit and the data signal line drive circuit,

wherein at least the scanning signal lines, the data signal lines, or the plurality of types of wirings are wirings having a laminated structure including a lower layer wiring and an upper layer wiring that is formed to cover at least a part of a surface of the lower layer wiring.

A second aspect of the present invention provides the display device according to the first aspect of the present invention, wherein the upper layer wiring is formed to cover an upper surface and both side surfaces of the lower layer wiring.

A third aspect of the present invention provides the display device according to the first aspect of the present invention, wherein the plurality of types of wirings include a gate lead line connected to the scanning signal line, a source lead line connected to the data signal line, and a power line connected to the scanning signal line, and are wirings formed in a same manufacturing step as the scanning signal line.

A fourth aspect of the present invention provides the display device according to the first aspect of the present invention,

wherein the lower layer wiring is formed of any one of a titanium layer, a copper layer, an aluminum layer, an aluminum alloy layer, a tungsten layer, a chromium layer, and an aluminum-silicon layer, and the upper layer wiring is formed of one of a molybdenum-niobium layer and a molybdenum layer.

A fifth aspect of the present invention provides the display device according to the first aspect of the present invention,

wherein the lower layer wiring is a laminated wiring formed of any one of combinations: a titanium layer and an aluminum layer; a titanium layer and a copper layer; a titanium layer and an aluminum alloy layer; a titanium layer and a tungsten layer; a titanium layer and a chromium layer; a titanium layer and a tantalum layer; a copper layer and a tungsten layer; a copper layer and a chromium layer; and a copper layer and a tantalum layer, where one of the combination is provided as a lower layer and the other is provided as an upper layer, and the upper layer wiring is formed of one of a molybdenum-niobium layer and a molybdenum layer.

A sixth aspect of the present invention provides the display device according to the first aspect of the present invention, wherein the lower layer wiring is a laminated wiring sandwiching any one of an aluminum layer, a copper layer, an aluminum alloy layer, a tungsten layer, a chromium layer, a tantalum layer, and an aluminum-silicon layer between titanium layers, or a laminated wiring sandwiching an aluminum layer between a titanium nitride layer and a titanium layer, and the upper layer wiring is formed of one of a molybdenum-niobium layer and a molybdenum layer.

A seventh aspect of the present invention provides a method for manufacturing the display device according to the first aspect of the present invention, the method including: a first photolithography step of forming a first resist pattern for patterning the lower layer wiring;

a first etching step for forming the lower layer wiring with the first resist pattern as a mask;

a second photolithography step of forming a second resist pattern for patterning the upper layer wiring; and

a second etching step for forming the lower layer wiring with the second resist pattern as a mask,

wherein a photomask used in the second photolithography step is a same mask as a photomask that is used in the first photolithography step.

An eighth aspect of the present invention provides the method according to the seventh aspect of the present invention, wherein an amount of exposure at a time of forming the second resist pattern is smaller than an amount of exposure at a time of forming the first resist pattern.

A ninth aspect of the present invention provides the method according to the seventh aspect of the present invention, wherein the lower layer wiring is formed in the first etching step by a dry etching method, and the upper layer wiring is formed in the second etching step by a wet etching method using an etchant with a high selectivity of the upper layer wiring to the lower layer wiring.

A tenth aspect of the present invention provides the method according to the ninth aspect of the present invention, wherein the etchant is a phosphoric-nitric-acetic acid aqueous solution.

### Effects of the Invention

According to the first aspect described above, at least the scanning signal lines, the data signal lines, or the plurality of types of wirings connected, respectively, to the scanning signal line drive circuit and the data signal line drive circuit are wirings having a laminated structure including a lower layer wiring and an upper layer wiring that is formed to cover a surface of the lower layer wiring. Accordingly, even if the lower layer wiring includes a part where the line width is narrowed and which is nearly disconnected due to a particle or the like attached at the time of formation of the lower layer wiring, the probability is extremely low that a particle is attached again to the upper layer wiring at the time of formation of the upper layer wiring, at a position corresponding to the nearly disconnected part of the lower layer wiring. Moreover, the lower layer wiring and the upper layer wiring are electrically connected to each other. Accordingly, even if the narrowed part of the lower layer wiring is disconnected due to later use by a user, the wiring having the laminated structure is conducted through the upper layer wiring. A display device including a highly reliable wiring as described above can continuously display an image normally even if the lower layer wiring is disconnected during use. The same is applied to a case where the upper layer wiring includes a part where the line width is narrowed and which is nearly disconnected due to a particle attached at the time of formation of the upper layer wiring, for example.

According to the second aspect described above, because the upper layer wiring is formed to cover the upper surface and both side surfaces of the lower layer wiring, a more advantageous effect than that of the first aspect may be obtained.

According to the third aspect described above, the scanning signal line, the gate lead line, the source lead line, and the power line are wirings having a laminated structure including a lower layer wiring and an upper layer wiring which is formed to cover the surface of the lower layer wiring, and thus, these wirings may achieve the same effect as that of the first aspect.

According to the fourth aspect described above, by forming the lower layer wiring by a single-layer metal layer, a wiring having a laminated structure which is not easily disconnected can be realized by a simple structure. Moreover, with such a structure, the manufacturing process of the wiring can be reduced, and the material cost can be suppressed, and thus, the manufacturing cost of the wiring can be reduced.

According to the fifth aspect described above, the same effect as that of the fourth aspect can be obtained.

According to the sixth aspect described above, the metal layer of the lower layer wiring is sandwiched between titanium layers or titanium nitride layers which are not easily etched at the time of etching of the upper layer wiring, and thus, the lower layer wiring is not easily corroded at the time of etching of the upper layer wiring. The reliability of the wiring can thereby be increased.

According to the seventh aspect described above, the same mask as the photomask used in the first photolithography step to form the first resist pattern for patterning the lower layer wiring is used as the photomask to be used in the second photolithography step for forming the second resist pattern for patterning the upper layer wiring. Using the same mask eliminates the need to take into account the misregistration between the patterns caused at the time of fabrication of photomasks and a shift due to variance in the line widths, and the shift of the upper layer wiring with respect to the pattern of the lower layer wiring will depend only on the alignment accuracy in the alignment step. Therefore, the pattern of the upper layer wiring can be positioned with respect to the pattern of the lower layer wiring with a smallest shift, and the reliability of the wiring having the laminated structure can be further increased. Moreover, because the number of photomasks to be fabricated is reduced, the manufacturing cost of the liquid crystal display device can be reduced.

According to the eighth aspect described above, in the case of performing exposure using the same photomask in the photolithography steps, the amount of exposure in the photolithography step for forming the upper layer wiring is reduced compared to the amount of exposure in the photolithography step for forming the lower layer wiring. The wiring width of the upper layer wiring is thereby made greater than the wiring width of the lower layer wiring, and the upper layer wiring is formed to cover the entire surface of the lower layer wiring. By using the same photomask in the photolithography step for forming the lower layer wiring and in the photolithography step for forming the upper layer wiring and reducing the amount of exposure in the photolithography step for forming the upper layer wiring as described above, the misregistration between the patterns of the upper layer wiring and the lower layer wiring can be reduced, and the upper layer wiring that covers the entire surface of the lower layer wiring can be formed.

According to the ninth aspect described above, an etchant with a high selectivity is used in the second etching step for forming the upper layer wiring, and thus, corrosion of the lower layer wiring at the time of etching for forming the upper layer wiring can be suppressed as much as possible. The lower layer wiring can thus be made less susceptible to damage at the time of formation of the upper layer wiring.

According to the tenth aspect described above, the selectivity of the upper layer wiring to the lower layer wiring may be increased by using a phosphoric-nitric-acetic acid aqueous solution as the etchant for forming the upper layer wiring, and thus, the lower layer wiring can be made less susceptible to damage at the time of formation of the upper layer wiring.

### BRIEF DESCRIPTION OF THE DRAWINGS

FIGS. 1(A) to 1(C) are diagrams showing an example of an influence exerted on a wiring pattern by a particle attached to a region where a wiring is to be formed, and more particularly, FIG. 1(A) is a diagram showing a particle which is attached to a metal film and which is partially under a resist pattern, FIG. 1(B) is a diagram showing an opening formed in the resist pattern due to removal of the particle, and FIG. 1(C) is a diagram showing a shape of a wiring that is formed by etching the metal film.

FIG. 2 is a block diagram showing a configuration of a liquid crystal display device according to a first embodiment.

FIG. 3 is a plan view showing an arrangement of wirings formed in the liquid crystal display device shown in FIG. 2.

FIG. 4 is a cross-sectional diagram showing a cross-section of a first wiring shown in FIG. 3.

FIGS. 5(A) and 5(B) are diagrams showing a case where a wiring structure of the present invention is applied to a scanning signal line including a chipped pattern or a part that is nearly disconnected, and more particularly, FIG. 5(A) is a diagram showing a case where a scanning signal line is formed of only a lower layer wiring, and FIG. 5(B) is a diagram showing a case where the wiring structure of the present invention is applied to a scanning signal line.

FIG. 6 is a flowchart showing manufacturing process of the first wiring shown in FIG. 3.

FIGS. 7(A) to 7(E) are cross-sectional diagrams showing manufacturing process of the first wiring and a second wiring shown in FIG. 3, and more particularly, FIGS. 7(A) to 7(E) are cross-sectional diagrams showing the first wiring and the second wiring in respective manufacturing steps.

FIGS. 8(F) to 8(J) are cross-sectional diagrams showing manufacturing process of the first wiring and the second wiring formed in the liquid crystal display device shown in FIG. 2, and more particularly, FIGS. 8(F) to 8(J) are cross-sectional diagrams showing the first wiring and the second wiring in respective manufacturing steps.

FIG. 9 is a diagram showing main conditions of an etching step shown in FIG. 6.

FIGS. 10(A) and 10(B) are diagrams comparing the defective rate of the wiring formed in the liquid crystal display device shown in FIG. 2 and the defective rate of a conventional wiring, and more particularly, FIG. 10(A) is a diagram comparing the rate of disconnection defect found in an inspection step during a manufacturing process of an 8 WVGA liquid crystal panel between the first wiring of the present invention and the conventional wiring, and FIG. 10(B) is a diagram comparing the rate of disconnection defect which occurred after shipping of the 8 WVGA liquid crystal panel as a product between the first wiring of the present invention and the conventional wiring.

FIG. 11 is a cross-sectional diagram of a first wiring that is formed in a liquid crystal display device according to a second embodiment.

FIG. 12 is a cross-sectional diagram of a first wiring that is formed in a liquid crystal display device according to a third embodiment.

FIG. 13 is a cross-sectional diagram of a first wiring that is formed in a liquid crystal display device according to a modification of the third embodiment.

### MODES FOR CARRYING OUT THE INVENTION

### 0. Basic Study

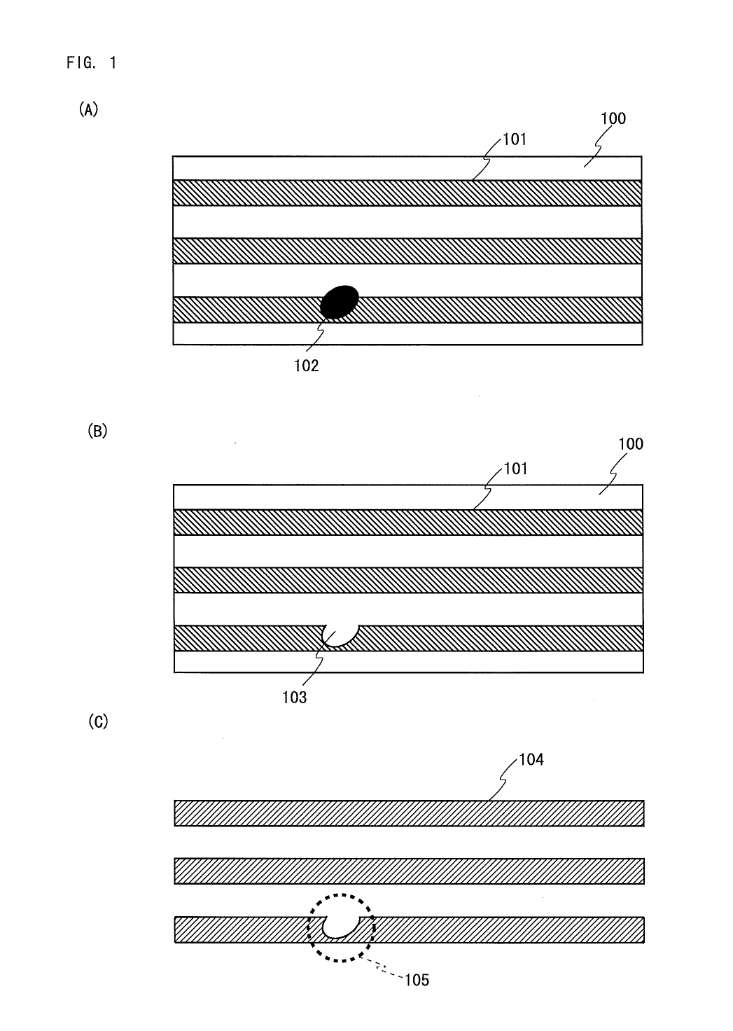

Problems occurring due to particles that are attached to the surface of a metal film deposited by a sputtering method or the like at the time of forming a wiring on an insulating substrate will be described. FIGS. 1(A) to 1(C) are diagrams showing an example of an influence exerted on a wiring pattern by a particle attached to a region where a wiring is to be formed, and more particularly, FIG. 1(A) is a diagram showing a particle 102 which is attached to a metal film 100 and which is partially under a resist pattern 101, FIG. 1(B) is a diagram showing an opening 103 formed in the resist pattern 101 due to removal of the particle 102, and FIG. 1(C) is a diagram showing a shape of a wiring 104 that is formed by etching the metal film 100 with the resist pattern 101 as a mask.

As shown in FIG. 1(A), a particle 102 having a size of about 2 μm to 10 μm is attached to the metal film 100 deposited by the sputtering method or the like, and the resist pattern 101 as a mask for forming the wiring 104 is formed in a state where the particle 102 is attached. As shown in FIG. 1(B), the particle 102 comes off during etching for forming the wiring 104 by using the resist pattern 101 as a mask, and the opening 103 is thereby formed at the position where the particle 102 was attached, and the surface of the metal film 100 which is to be the wiring 104 becomes exposed. As shown in FIG. 1(C), when etching of the metal film 100 is further performed by using the resist pattern 101 as a mask, and the resist pattern 101 is striped after the etching is ended, the width of the wiring 104 which is to have a predetermined width is narrowed at a portion 105. Note that, the particle 102 is a particle which was attached, at the time of deposition of the metal film 100 on an insulating substrate, to a mask for controlling the deposition position of the metal film 100 and to an adhesion preventive plate that functions as a support member for fixing the insulating substrate at the time of deposition but was then peeled off, and its component is the same as that of the metal film 100.

Such a wiring 104 having the portion 105 where the width is narrowed is difficult to find by inspection before shipping of the liquid crystal display device, and the liquid crystal display device is sometimes shipped as a non-defective product. However, when a user uses the liquid crystal display device over a long period of time, an electrical, thermal or mechanical stress or the like is repeatedly applied to the portion 105 where the width of the wiring 104 is reduced. This causes the wiring 104 to be disconnected at the narrow portion 105, and the liquid crystal display device may not operate normally. Note that, an attached particle may come off by being washed off by a developing solution at the time of development instead of coming off by having its peripheral portion etched at the time of etching. Also in such a case, the metal film 100 which is to be the wiring 104 is partially etched, and the wiring 104 becomes narrow.

Accordingly, a structure for causing the wiring 104, which is partially narrowed at the time of patterning of the metal film 100 due to attachment of the particle 102 to the metal film 100 at a region where the wiring 104 is to be formed, to be a highly reliable wiring will be considered.

The positions where particles are attached during deposition of a metal film are random, and in the case of deposition of two layers of metal films, it is assumed that the positions of particles attached to the metal films will be highly unlikely the same. Accordingly, formation of a wiring by patterning two metal layers will be considered. As described above, if a wiring is formed of only one layer of metal film, depending on the position where the particle is attached, the wiring may be partially narrowed or be completely disconnected. Accordingly, a wiring at a second layer is formed by depositing a metal film at a second layer on a wiring that is formed by patterning a metal film at a first layer, and by patterning the metal film at the second layer. According to such a laminated wiring including two layers of metal films formed in the above manner, the wiring at the first layer and the wiring at the second layer are electrically connected to each other.

In this case, a particle is possibly attached also to the metal film at the second layer, but because positions of attachment are random, the probability is extremely low that the particle is attached at the same position as the position of attachment at the time of deposition of the metal film at the first layer. Accordingly, the part of the wiring formed by the metal film at the second layer which is narrowed due to the influence of a particle and is susceptible to disconnection is quite likely to be different from the part of the wiring formed by the metal film at the first layer which is narrowed and is susceptible to disconnection. Therefore, even if one of the wirings at the first layer and the second layer is disconnected at a part which is susceptible to disconnection due to stress applied at the time of use, conductivity of the wiring is maintained through the other wiring which is not disconnected.

### 1. First Embodiment

### 1.1 Configuration of Liquid Crystal Display Device

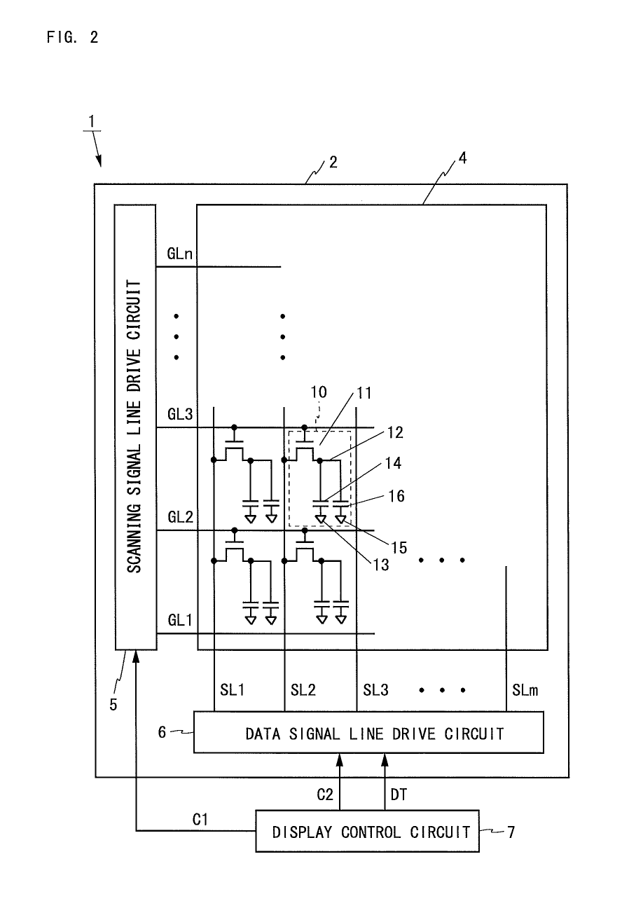

FIG. 2 is a block diagram showing a configuration of a liquid crystal display device 1 according to the first embodiment. As shown in FIG. 2, the liquid crystal display device 1 is an active matrix-type display device including, on an insulating substrate (array substrate) 2, a display unit 4, a scanning signal line drive circuit 5, a data signal line drive circuit 6, and a display control circuit 7.

The display unit 4 is provided with a plurality (m) of data signal lines SL1 to SLm, a plurality (n) of scanning signal lines GL1 to GLn, and a plurality (m×n) of pixel formation portions 10 provided in correspondence with respective intersections of the m data signal lines SL1 to SLm and the n scanning signal lines GL1 to GLn. The pixel formation portions 10 are arranged two-dimensionally, m in the row direction and n in the column direction. The scanning signal line GLi is commonly connected to the pixel formation portions 10 arranged at an i-th row, and the data signal line SLj is commonly connected to the pixel formation portions 10 arranged at a j-th column. Note that, m and n are integers of two or more.

Each pixel formation portion 10 includes a thin film transistor (sometimes referred to as “TFT”) 11 having a gate electrode connected to the scanning signal line GLi passing through a corresponding intersection and a source electrode connected to the data signal line SLj passing through the intersection, a pixel electrode 12 connected to a drain electrode of the TFT 11, a common electrode 13 commonly provided to the m×n pixel formation portions 10, and a liquid crystal layer (not shown) sandwiched between the pixel electrode 12 and the common electrode 13 and commonly provided to the plurality of pixel formation portions 10, and the pixel electrode 12, the common electrode 13, and the liquid crystal layer form a pixel capacitance 14. Furthermore, to reliably retain voltage according to image data, an auxiliary capacitance 16 formed of the pixel electrode 12, an auxiliary capacitance line 15, and the liquid crystal layer is provided in parallel to the pixel capacitance 14.

Based on a control signal and image data supplied from outside, the display control circuit 7 outputs a control signal C1 to the scanning signal line drive circuit 5, and outputs a control signal C2 and image data DT to the data signal line drive circuit 6. The scanning signal line drive circuit 5 sequentially outputs high-level clock signals GCK, one at a time to the scanning signal lines GL1 to GLn. Accordingly, the scanning signal lines GL1 to GLn supplied with the high-level clock signals GCK are sequentially selected and activated one at a time, and the pixel formation portions 10 of one row connected to a selected scanning signal line GLi are placed in a state where collective writing of a source signal according to the image data DT is enabled. The data signal line drive circuit 6 is controlled by the control signal C2, and applies a source signal according to the image data DT to the data signal lines SL1 to SLm. Accordingly, a source signal is written in the pixel formation portions 10 of one row connected to the selected scanning signal line GLi. The liquid crystal display device 1 thus displays an image.

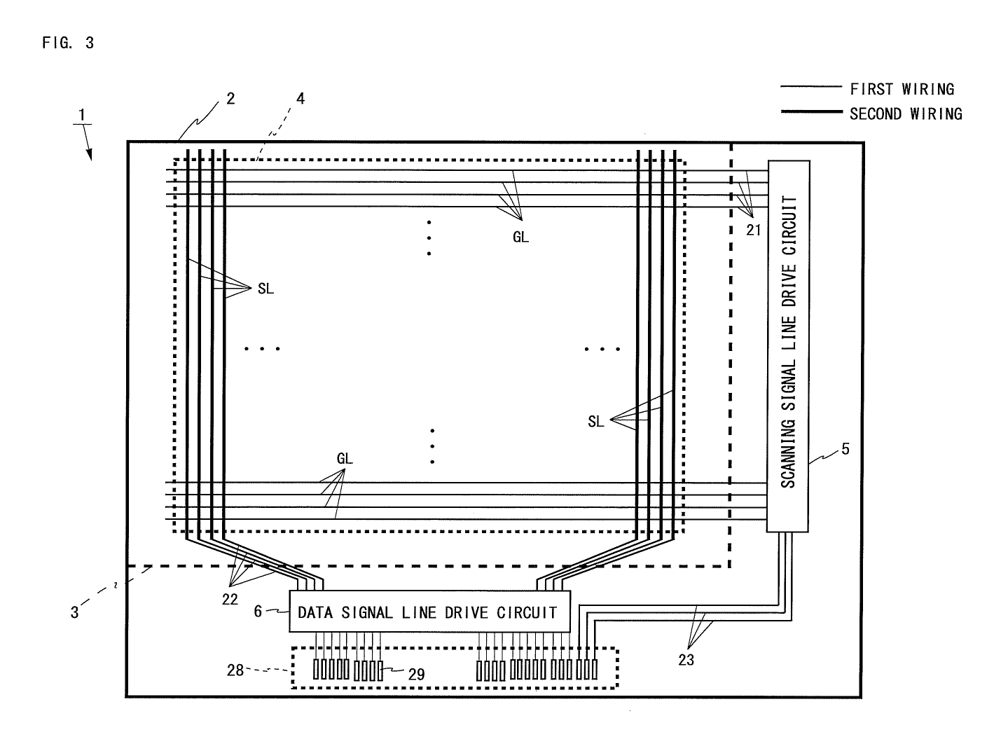

FIG. 3 is a plan view showing an arrangement of wirings formed in the liquid crystal display device 1. As shown in FIG. 3, the liquid crystal display device 1 has an array substrate 2, and a counter substrate 3, which are formed of a glass plate or the like and stuck together, and the display unit 4 for displaying images, texts and the like is provided at a center portion. The display unit 4 is provided with a plurality of scanning signal lines GL formed in the horizontal direction, a plurality of data signal lines SL formed in the vertical direction, and pixel formation portions (not shown) formed at the intersections.

The scanning signal line drive circuit 5 for driving the scanning signal lines GL and the data signal line drive circuit 6 for driving the data signal lines SL are disposed at a region (frame) of the array substrate 2 where the counter substrate 3 is not stuck. The scanning signal line drive circuit 5 and the data signal line drive circuit 6 may be monolithically formed with the display unit 4, or semiconductor chips having the functions may be mounted to the frame of the array substrate 2. In FIG. 3, the scanning signal lines GL are sequentially activated by the scanning signal line drive circuit 5, which is a semiconductor chip mounted on the frame on the right side of the display unit 4, and a voltage (source signal) according to the image data DT is applied to each data signal line SL by the data signal line drive circuit 6, which is a semiconductor chip mounted on the frame on the lower side of the display unit 4. The image data DT and the control signals C1 and C2 are supplied to the scanning signal line drive circuit 5 and the data signal line drive circuit 6 from an external display control circuit (not shown) via respective FPC (flexible printed circuit) connection terminals 29 provided in a connection portion 28, provided on the array substrate 2.

A wiring that is formed on such a liquid crystal display device 1 will be described. Gate lead lines 21 for connecting the scanning signal line drive circuit 5 and respective scanning signal lines GL, source lead lines 22 for connecting the data signal line drive circuit 6 and respective data signal lines SL, and power lines 23 for supplying power source voltage and various control signals to the scanning signal line drive circuit 5 are formed on the array substrate 2. Each of these wirings 21 to 23 is formed simultaneously at the time of forming the scanning signal line GL or the data signal line SL. Accordingly, in the present specification, the scanning signal line GL and the wiring that is formed simultaneously at the time of forming the scanning signal line GL will be referred to as a “first wiring”, and the data signal line SL and the wiring that is formed simultaneously at the time of forming the data signal line SL will be referred to as a “second wiring”.

The first wiring includes the scanning signal line GL, the gate lead line 21, the source lead line 22, and the power line 23, and in the case of a liquid crystal display device of a vertical electric field method, an auxiliary capacitance line (not shown) is further included. On the other hand, the second wiring includes the data signal line SL. Here, the scanning signal line GL is integrally formed with the gate electrode of the TFT 11, and the entire scanning signal line GL including the gate electrode is the first wiring. Also, in the case where the scanning signal line drive circuit 5 and the data signal line drive circuit 6 are monolithically formed, the scanning signal line drive circuit 5 and the data signal line drive circuit 6 are configured by a wiring formed in the same step as the first wiring, and a wiring formed in the same step as the second wiring. In this case, the wirings 21 to 23, which correspond to the first wiring, are simultaneously formed in the same manufacturing process as the scanning signal line GL, and thus are covered by insulating films such as the gate insulating film and a passivation film which are formed later. Accordingly, the wirings 21 to 23 are protected by insulating films, and have increased environmental resistance, such as moisture resistance, and are less susceptible to mechanical damage, such as a scratch.

Note that, the source lead line 22 may be formed simultaneously with the data signal line SL. In this case, if connection terminals are formed at respective end portions of the gate lead line 21 and the source lead line 22, the heights of the connection terminals from the array substrate 2 become different. If a semiconductor chip serving as the scanning signal line drive circuit 5 and a semiconductor chip serving as the data signal line drive circuit 6 are pressure-bonded at the same time to the connection terminals at different heights, the pressure-bonding strength becomes different between the semiconductor chips, causing connection resistance values to be varied. Accordingly, in the case of forming the source lead line 22 simultaneously with the data signal line SL, which is the second wiring, a connection terminal for pressure-bonding the semiconductor chip serving as the data signal line drive circuit 6 has to be formed simultaneously with the scanning signal line GL, and the source lead line 22 formed simultaneously with the data signal line SL has to be connected to the connection terminal.

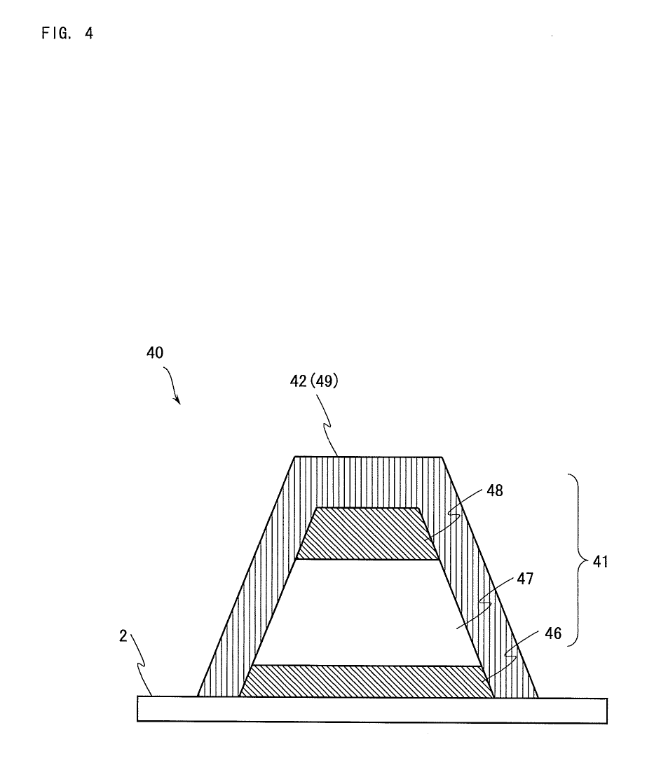

FIG. 4 is a cross-sectional diagram showing the structure of a first wiring 40. As shown in FIG. 4, the first wiring 40 includes, on the array substrate 2, a lower layer wiring 41 and an upper layer wiring 42 formed to cover the upper surface and both side surfaces of the lower layer wiring 41. The lower layer wiring 41 has a laminated structure in which a first titanium layer 46, an aluminum layer 47, and a second titanium layer 48 are stacked in this order from the array substrate 2 side, and the upper layer wiring 42 is a wiring having a single-layer structure formed of a molybdenum-niobium layer 49. In the lower layer wiring 41, sandwiching the aluminum layer 47 between the first and second titanium layers 46, 48 prevents occurrence of hillock at the aluminum layer 47 or prevents aluminum atoms from diffusing from the aluminum layer 47 to a channel layer of the TFT and affecting the property of the TFT.

In the first wiring 40 as described above, the lower layer wiring 41 is tapered on both sides. Furthermore, the upper layer wiring 42 formed of the molybdenum-niobium (MoNb) layer 49 is formed to cover the upper surface and both side surfaces of the lower layer wiring 41, and the upper layer wiring 42 is also tapered on both sides in the same manner as the lower layer wiring 41, and its taper angle is the same as the taper angle of the lower layer wiring 41. The lower layer wiring 41 and the upper layer wiring 42 forming the first wiring 40 are tapered on both sides in the above manner so as to prevent step-cut of an insulating film such as the gate insulating film that is formed to cover the first wiring 40 after formation of the first wiring 40, due to poor step coverage on the side surfaces of the first wiring 40.

Even if a part of the lower layer wiring 41 of the first wiring 40 is narrowed due to a particle, the probability is extremely low that a particle is attached again to a position of the upper layer wiring 42 corresponding to the part of the lower layer wiring 41 to thereby reduce the wiring width of also the upper layer wiring 42. Therefore, because the wiring structure of the first wiring 40 is a two-layer structure, even if the lower layer wiring 41 includes a part that is nearly disconnected, the conductivity of the first wiring 40 at the part is maintained through the upper layer wiring 42. By using a wiring having such a structure as the wiring of the liquid crystal display device 1, cases where the wiring is disconnected during use by a user and an image is not displayed normally can be greatly reduced.

The wiring structure of the second wiring is the same as the wiring structure of the first wiring 40 shown in FIG. 4, and thus, a cross-sectional diagram of the second wiring is omitted. Similarly to the wiring structure of the first wiring 40, the wiring structure of the second wiring also includes a lower layer wiring having a laminated structure in which a first titanium layer, an aluminum layer, and a second titanium layer are stacked in this order from the array substrate 2 side, and an upper layer wiring which is a molybdenum-niobium layer which is formed to cover the surface of the lower layer wiring. Accordingly, the same effect as that of the wiring structure of the first wiring 40 can be obtained by the wiring structure of the second wiring. Moreover, to prevent step-cut of the insulating film, the lower layer wiring and the upper layer wiring are tapered on both sides.

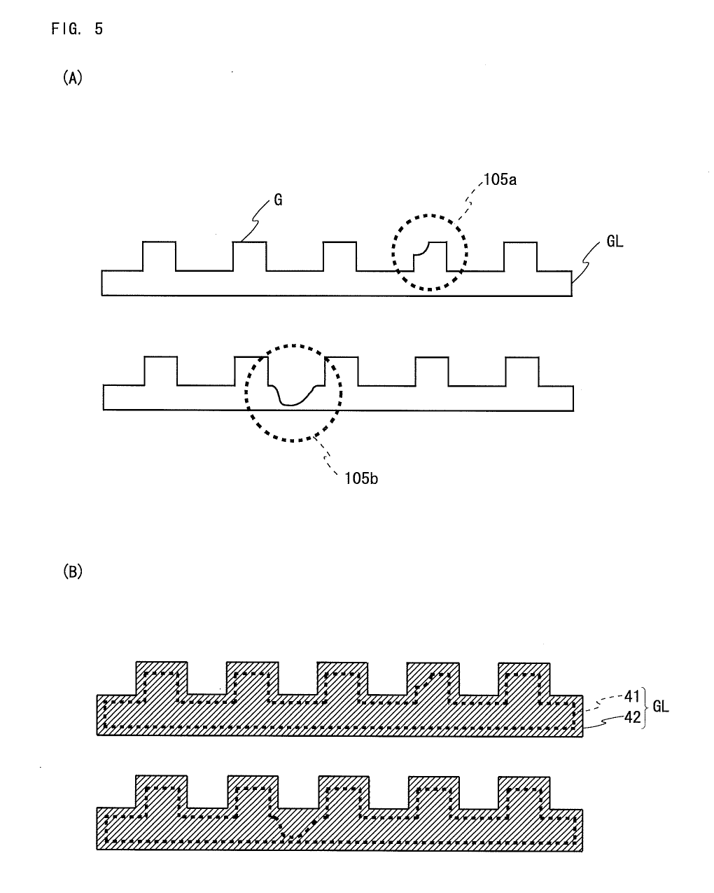

FIGS. 5(A) and 5(B) are diagrams showing a case where a wiring structure of the present invention is applied to the scanning signal line GL including a chipped pattern or a part that is nearly disconnected, and more particularly, FIG. 5(A) is a case where the scanning signal line GL is formed of only the lower layer wiring 41, and FIG. 5(B) is a diagram showing a case where the wiring structure of the present invention is applied to the scanning signal line GL. As shown in FIG. 5(A), in the case where the scanning signal line GL is formed of only the lower layer wiring 41, a fault portion 105a where the pattern of a gate electrode G is partially chipped, or a fault portion 105b where the wiring is partially narrowed and nearly disconnected is formed in the scanning signal line GL due to a particle attached to the surface of the metal film. When the pattern of the gate electrode G is partially chipped, the property of the TFT may be greatly affected. Also, when the scanning signal line GL is partially narrowed, the scanning signal line GL may be partially disconnected due to repeated use. Accordingly, the scanning signal line GL is a wiring including the lower layer wiring 41 and the upper layer wiring 42 as shown in FIG. 5(B). In this case, at the time of forming the upper layer wiring 42, the possibility is low that a fault portion of the upper layer wiring 42 due to a particle occurs at the same position as the fault portion 105a, 105b shown in FIG. 5(A), and the conductivity of the scanning signal line GL can be maintained through the upper layer wiring 42, and also, the shape of the gate electrode G can be made normal so as not to affect the property of the TFT.

### 1.2 Method for Manufacturing Wiring

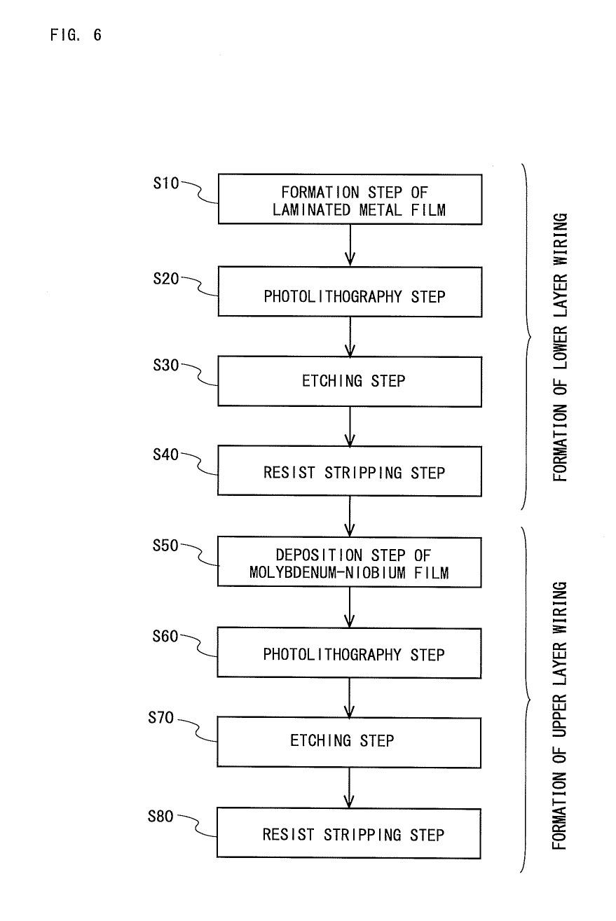

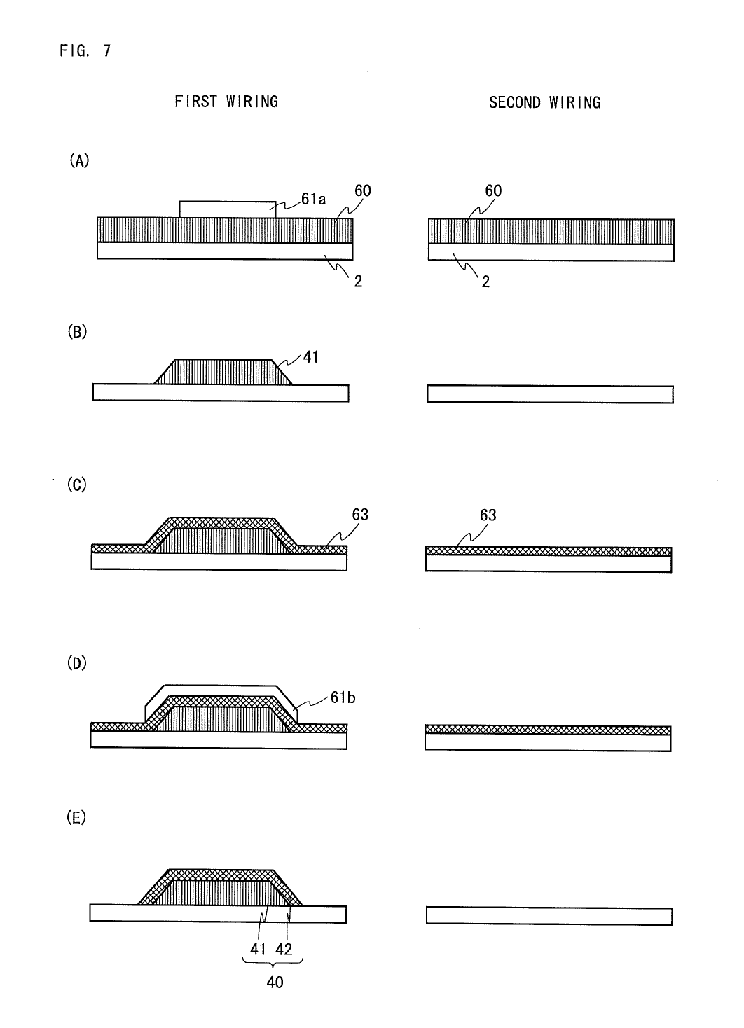

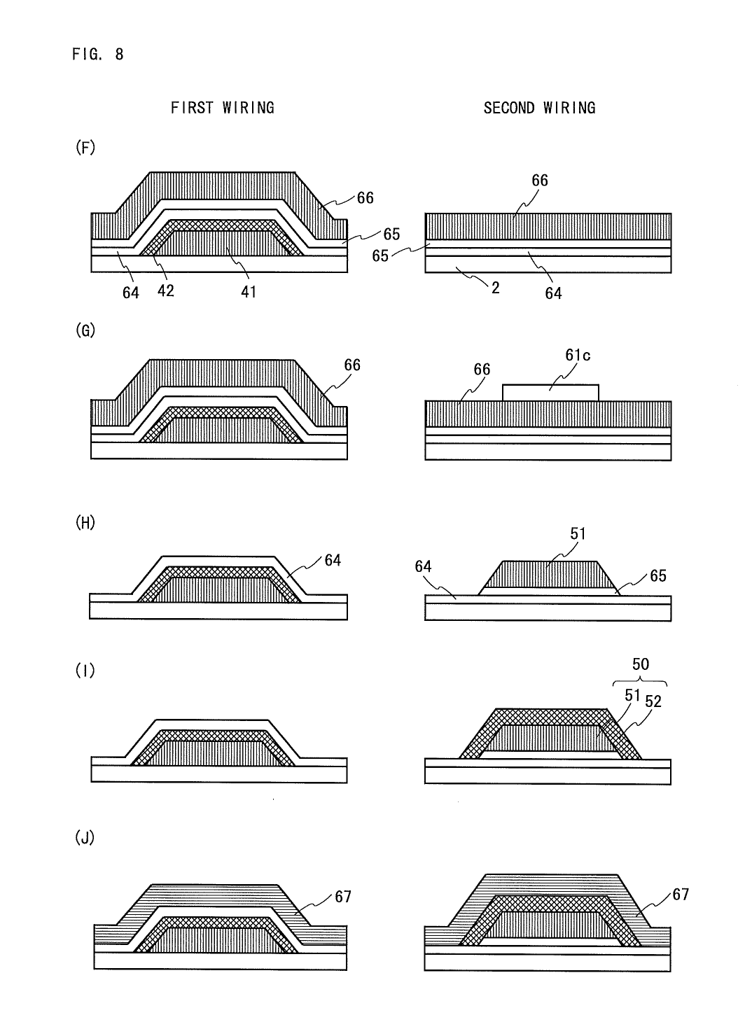

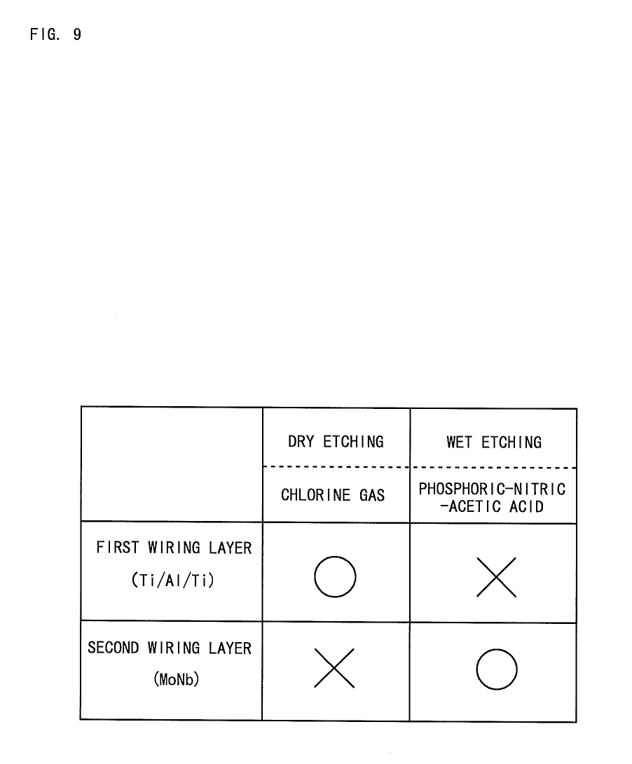

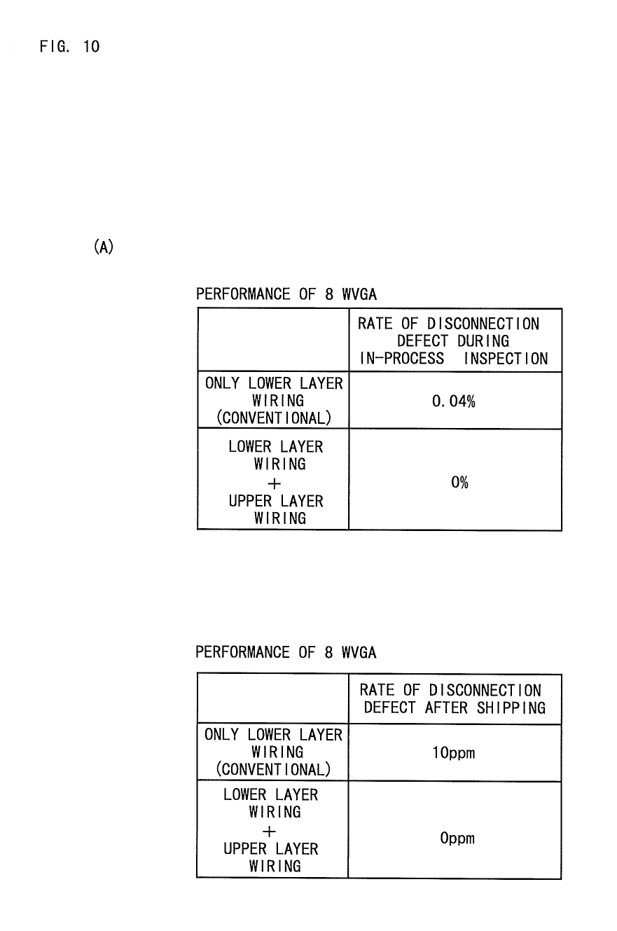

Next, a method for manufacturing the first wiring 40 and a second wiring 50 having the wiring structure described above will be described. FIG. 6 is a flowchart showing manufacturing process of the first wiring 40 of the present embodiment. Also, FIGS. 7(A) to 7(E) and FIGS. 8(F) to 8(J) are cross-sectional diagrams showing manufacturing process of the first wiring 40 and the second wiring 50, and more particularly, FIGS. 7(A) to 7(E) and FIGS. 8(F) to 8(J) are cross-sectional diagrams of the first wiring 40 and the second wiring 50 in respective manufacturing steps. Furthermore, FIG. 9 is a diagram showing main conditions of etching steps in step S30 and step S70 shown in FIG. 6. Note that, in each of FIGS. 7(A) to 7(E) and FIGS. 8(F) to 8(J), a cross-section of the first wiring 40 is shown on the left side, and a cross-section of the second wiring 50 is shown on the right side. In the following, the method for manufacturing the first wiring 40 and the second wiring 50 will be described with reference to FIGS. 6 to 9.

First, an outline of manufacturing process will be given with reference to FIG. 6. As shown in FIG. 6, in a formation step of a laminated metal film in step S10, a laminated metal film is formed by depositing a titanium film, an aluminum film, and a titanium film in this order. In a photolithography step in step S20, a resist pattern is formed on the surface of a laminated metal film which is to be the lower layer wiring 41 of the first wiring 40. In an etching step in step S30, the laminated metal film is etched by using a dry etching method, and the lower layer wiring 41 is formed. In a resist stripping step in step S40, the resist pattern formed in step S20 is stripped. The lower layer wiring 41 is formed by the steps up to this point.

Next, in a deposition step of a molybdenum-niobium film in step S50, a molybdenum-niobium film which is to be the upper layer wiring 42 of the first wiring 40 is deposited. In a photolithography step in step S60, a resist pattern is formed on the surface of the molybdenum-niobium film. The photomask used in the photolithography step is the same mask as the photomask that is used in the photolithography step in step S20. However, the amount of exposure in step S60 is smaller than that in step S20.

In an etching step in step S70, the molybdenum-niobium film is etched by using a wet etching method, and the upper layer wiring 42 is formed. In the etching, an etchant with a high etch selectivity (etching speed) between the molybdenum-niobium film and the titanium film is used. Accordingly, the titanium film is hardly etched in a period until the end of etching of the molybdenum-niobium film. In a resist stripping step in step S80, the resist pattern formed in step S60 is stripped. The upper layer wiring 42 is formed by the steps from step S50 to step S80. Note that, the second wiring is formed by repeating the same steps as steps S10 to S80 described above, and description thereof is omitted.

Next, the method for manufacturing the first and second wirings 40, 50 will be described with reference to FIGS. 7(A) to 7(E) and FIGS. 8(F) to 8(J). First, as shown in FIG. 7(A), a laminated metal film 60 is formed by depositing metal films, i.e., a titanium film, an aluminum film, and a titanium film, each having a predetermined film thickness, on the array substrate 2 in this order by using the sputtering method. A resist is applied on the laminated metal film 60, and a resist pattern 61a is formed by performing exposure/development by using a photomask. At this time, to taper the side surfaces of the lower layer wiring 41, post-baking is performed at the time of formation of the resist pattern 61a under the condition of tapering end portions. As shown in FIG. 7(B), the metal films forming the laminated metal film 60 are sequentially etched by the dry etching method with the resist pattern 61a as the mask. As shown in FIG. 9, this etching is performed under a known etching condition that mainly uses chlorine gas, and then, the resist pattern 61a is stripped. The lower layer wiring 41 of the first wiring 40 is thus formed. In this etching, polymer that is generated at the time of etching is accumulated at side walls simultaneously with the etching of the laminated metal film 60, and thus, the lower layer wiring 41 becomes tapered on the side surfaces. Note that, the laminated metal film 60 including a titanium film, an aluminum film, and a titanium film is also formed at a region where the second wiring 50 is to be formed. However, because a resist pattern is not formed on the laminated metal film 60, the laminated metal film 60 is removed at the time of dry etching, and the surface of the array substrate 2 is exposed.

Next, as shown in FIG. 7(C), a molybdenum-niobium film 63 is deposited by the sputtering method. The film thickness of the molybdenum-niobium film 63 is 30 nm to 200 nm. If the film thickness is less than 30 nm, deposition by a uniform film thickness becomes difficult, and if the film thickness is more than 200 nm, the throughput is reduced. At this time, the molybdenum-niobium film 63 is deposited also in the region where the second wiring 50 is to be formed.

Furthermore, as shown in FIG. 7(D), a resist is applied on the molybdenum-niobium film 63, and a resist pattern 61b is formed by performing exposure by using a photomask. The photomask used at this time is the same photomask as the photomask used for forming the resist pattern 61a in FIG. 7(A). However, the line width of the resist pattern 61b has to be made wide so that the resist pattern 61b after exposure/development covers the upper surface and both side surfaces of the lower layer wiring 41. Accordingly, exposure is performed with a smaller amount of exposure than in the case of FIG. 7(A). At this time, a resist pattern is not formed on the molybdenum-niobium film 63 which is deposited in a region where the second wiring 50 is to be formed.

Next, as shown in FIG. 7(E), the molybdenum-niobium film 63 is etched with the resist pattern 61b as the mask, and the upper layer wiring 42 is formed. As shown in FIG. 9, the etching for forming the upper layer wiring 42 is wet etching that is performed by using a known phosphoric-nitric-acetic acid aqueous solution in which phosphoric acid (H₃PO₄), nitric acid (HNO₃), and acetic acid (CH₃COOH) are mixed in a predetermined ratio. With the phosphoric-nitric-acetic acid aqueous solution, the etching speed of the molybdenum-niobium film 63 of the upper layer wiring 42 is greater than the etching speed of the titanium layer of the lower layer wiring 41 by ten times or more (i.e. the etch selectivity is higher by ten times or more), and the titanium layer that is exposed on the surface of the lower layer wiring 41 is hardly etched at the time of etching of the molybdenum-niobium film 63. The resist pattern 61b is then stripped. The upper layer wiring 42 that is electrically connected to the lower layer wiring 41 and that covers the upper surface and both side surfaces of the lower layer wiring 41 is thus formed. In this case, the molybdenum-niobium film 63 is deposited along the surface of the lower layer wiring 41, and thus, the upper layer wiring 42 is also tapered on both sides, and its taper angle is the same as the taper angle of the lower layer wiring 41. In this wet etching, the molybdenum-niobium film 63 at the region where the second wiring 50 is to be formed is removed, and the surface of the array substrate 2 is exposed again. The first wiring 40 is formed by the steps up to this point.

Next, as shown in FIG. 8(F), a gate insulating film 64, and a semiconductor film 65 which is to be a channel layer of a TFT are deposited in this order by a plasma chemical vapor deposition (CVD) method. These films are formed to cover the first wiring 40 at the region where the first wiring 40 is formed, and are stacked on the array substrate 2 at the region where the second wiring 50 is to be formed.

Furthermore, a laminated metal film 66 is formed on the semiconductor film 65 by using the sputtering method, the laminated metal film 66 including metal films, i.e., a titanium film, an aluminum film, and a titanium film, each having a predetermined film thickness, deposited in this order. Then, the same steps as the steps in FIGS. 7(A) to 7(E) described above are repeated. The second wiring 50 including a lower layer wiring 51 and an upper layer wiring 52 formed to cover the surface of the lower layer wiring 51 is thereby formed across the semiconductor film 65 on the gate insulating film 64 as shown in FIG. 8(J).

Then, a step for forming the TFT, and a step for forming a passivation film 67 for protecting the display unit and each wiring from the external environment are performed, and the liquid crystal display device 1 is manufactured. Note that, these steps are steps that are not directly relevant to the present invention, and detailed description thereof is omitted. The first wiring 40 and the second wiring 50 whose surfaces are covered by the passivation film 67 are thus formed.

In the description above, the second wiring 50 is, similarly to the first wiring 40, described as having two layers, i.e., the lower layer wiring 51 and the upper layer wiring 52, where the upper layer wiring 52 is a wiring that covers the entire surface of the lower layer wiring 51. However, the second wiring 50 may alternatively be a wiring having a single-layer structure including a metal layer which is the same as the metal layer forming the source/drain electrodes of the TFT, for example.

### 1.3 Improvements in Rate of Disconnection Defect

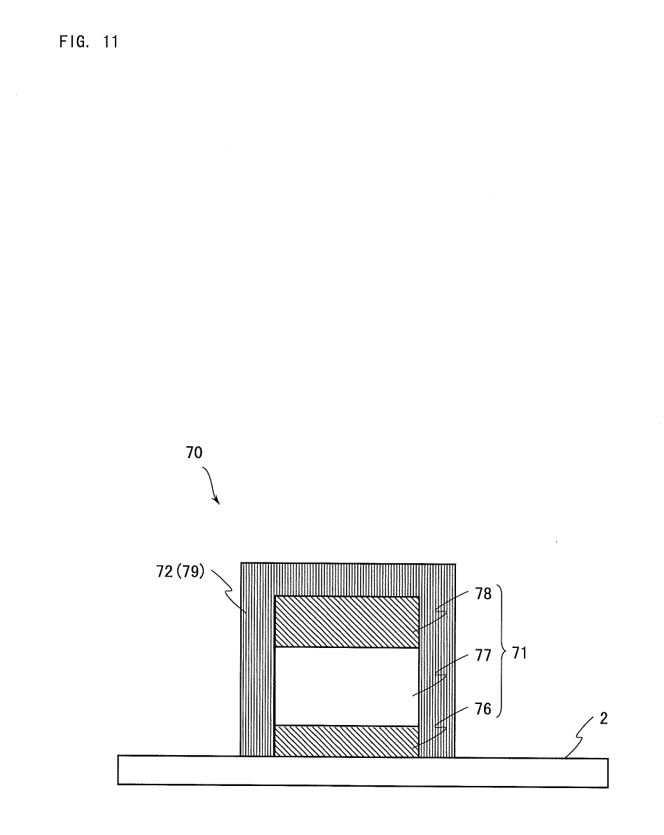

The ratio of occurrence of disconnection defect will be compared between a case where the first wiring is formed of only the lower layer wiring 41 and a case where the first wiring is formed of the lower layer wiring 41 and the upper layer wiring 42 which is formed to cover the upper surface and both side surfaces of the lower layer wiring 41. FIGS. 10(A) and 10(B) are diagrams comparing the defective rate of the first wiring of the present invention and the defective rate of a conventional wiring, and more particularly, FIG. 10(A) is a diagram comparing the rate of disconnection defect found in an inspection step during a manufacturing process of an 8 WVGA (Wide Video Graphics Array) liquid crystal panel between the first wiring of the present invention and the conventional wiring, and FIG. 10(B) is a diagram comparing the rate of disconnection defect which occurred after shipping of the 8 WVGA liquid crystal panel as a product between the first wiring of the present invention and the conventional wiring. As shown in FIG. 10(A), the conventional wiring is formed of only the lower layer wiring 41, and the rate of disconnection defect during in-process inspection in manufacturing process is 0.04%. However, since the first wiring of the present invention has a laminated structure, the rate of disconnection defect is 0%, and there is no occurrence of disconnection defect. Moreover, as shown in FIG. 10(B), the disconnection defect occurring after shipment of the product is 10 ppm for the conventional wiring, but is 0 ppm for the first wiring of the present invention and is greatly improved.

### 1.4 Effects

According to the present embodiment, the first wiring 40 is a wiring having a two-layer structure including the lower layer wiring 41 and the upper layer wiring 42 which is formed to cover the upper surface and both side surfaces of the lower layer wiring 41. Accordingly, even if the lower layer wiring 41 includes a part where the line width is narrowed and which is nearly disconnected due to a particle or the like attached at the time of formation of the lower layer wiring 41, the probability is extremely low that a particle is attached again, to the upper layer wiring 42 at the time of formation, at a position corresponding to the nearly disconnected part of the lower layer wiring 41. Also, because the upper layer wiring 42 is formed on the surface of the lower layer wiring 41, the wirings are electrically connected to each other. If the liquid crystal display device 1 including the first wiring having such a wiring structure is shipped as a product, even if the narrowed part of the lower layer wiring 41 is disconnected by repeated application of stress, such as electrical stress, due to use by a user, the first wiring 40 is a highly reliable wiring whose conductivity is maintained through the upper layer wiring 42, and the liquid crystal display device 1 can continuously display an image normally.

Also, even if the upper layer wiring 42 includes a narrowed part and the part is disconnected due to repeated use, it is highly unlikely that the wiring width of the lower layer wiring 41 corresponding to the disconnected position of the upper layer wiring 42 is also narrowed, and normally, conductivity of the first wiring 40 can be maintained through the lower layer wiring 41.

Furthermore, even if one of the upper layer wiring 42 and the lower layer wiring 41 is already disconnected at the time of completion of etching, the first wiring 40 having the laminated structure of the present invention is conducted through the other wiring which is not disconnected, and the first wiring 40 can function normally.

Furthermore, the photomask used for forming the resist pattern 61a which is the mask for etching the lower layer wiring 41 is used to form the resist pattern 61b which is to be the mask for etching the upper layer wiring 42. Following effects can thus be obtained. That is, if the shift of the pattern of the upper layer wiring 42 with respect to the pattern of the lower layer wiring 41 has to be suppressed to be within a predetermined range, using the same photomask eliminates the need to take into account the misregistration between the patterns caused at the time of fabrication of photomasks and a shift due to variance in the line widths, and the shift of the upper layer wiring 42 with respect to the pattern of the lower layer wiring 41 will depend only on the alignment accuracy. Therefore, the pattern of the upper layer wiring 42 can be positioned with respect to the pattern of the lower layer wiring 41 with a smallest shift. Moreover, because the number of photomasks to be fabricated is reduced, the manufacturing cost of the liquid crystal display device 1 can be reduced.

Furthermore, in the case where the same photomask is to be used in the photolithography steps, the amount of exposure in the photolithography step for forming the upper layer wiring 42 is reduced compared to the amount of exposure in the photolithography step for forming the lower layer wiring 41. This increases the wiring width of the upper layer wiring 42 compared to the wiring width of the lower layer wiring 41, enabling the upper layer wiring 42 to cover the upper surface and both side surfaces of the lower layer wiring 41. By using the same photomask in the photolithography step for forming the lower layer wiring 41 and in the photolithography step for forming the upper layer wiring 42 and reducing the amount of exposure in the photolithography step for forming the upper layer wiring 42 as described above, the misregistration between the patterns of the upper layer wiring 42 and the lower layer wiring 41 can be reduced, and the upper layer wiring 42 that covers the upper surface and both side surfaces can be formed.

Furthermore, if a material different from the metal material forming the lower layer wiring 41 is used as the metal material for forming the upper layer wiring 42, a mixed acid solution with sufficiently high selectivity to the lower layer wiring 41, such as the phosphoric-nitric-acetic acid aqueous solution, can be selected at the time of etching for forming the upper layer wiring 42. The lower layer wiring 41 can thus be made less susceptible to damage at the time of formation of the upper layer wiring 42.

Moreover, the lower layer wiring 41 includes the aluminum layer 47, which is highly conductive and inexpensive, and the first and second titanium layers 46, 48 formed to sandwich the aluminum layer 47. The first and second titanium layers 46, 48 have high environmental resistance with respect to moisture or the like entering from outside through the passivation film 67, and can sufficiently protect the aluminum layer 47. Furthermore, the molybdenum-niobium layer 49 forming the upper layer wiring 42 has high environmental resistance with respect to moisture or the like entering from outside, and thus the molybdenum-niobium layer 49 is not easily corroded by moisture. The reliability of the first wiring 40 can thus be maintained at a high level.

The effects of the present embodiment have been described with respect to the first wiring 40, but the same effects as in the case of the first wiring 40 can be obtained also in the case of the second wiring 50 having the same structure as the first wiring 40.

### 2. Second Embodiment

The configuration of a liquid crystal display device according to a second embodiment of the present invention, and the arrangement of wirings formed in the liquid crystal display device are the same as the configuration of the liquid crystal display device 1 shown in FIG. 2, and the arrangement of wirings shown in FIG. 3, respectively. Accordingly, in the present embodiment, a block diagram showing the configuration of the liquid crystal display device, a plan view showing the arrangement of wirings, and description thereof will be omitted.

A wiring structure of a first wiring 70 that is formed in the liquid crystal display device according to the present embodiment will be described in comparison to the wiring structure of the first wiring 40 of the liquid crystal display device 1 according to the first embodiment. FIG. 11 is a cross-sectional diagram showing a cross-section of the first wiring 70 according to the present embodiment. As shown in FIG. 11, the first wiring 70 includes a lower layer wiring 71 having a laminated structure in which a first titanium layer 76, an aluminum layer 77, and a second titanium layer 78 are stacked in this order from an insulating substrate side, and an upper layer wiring 72 which is formed to cover the surface of the lower layer wiring 71, and the upper layer wiring 72 is formed of a molybdenum-niobium layer 79. However, unlike in the case of the first embodiment, the lower layer wiring 71 and the upper layer wiring 72 of the first wiring 70 of the present embodiment are not tapered on both sides, and the side surfaces are approximately perpendicular to the array substrate 2.

Next, a method for manufacturing the first wiring 70 of the present embodiment will be described in comparison with the first wiring 40 of the first embodiment. The flowchart as shown in FIG. 6, and the cross-sectional diagrams of respective manufacturing steps as shown in FIGS. 7(A) to 7(E) and FIGS. 8(F) to 8(J) are approximately the same for the present embodiment. However, the processing conditions for the photolithography step in step S20 and the etching step in step S30 shown in FIG. 6 are partially different. In order to cause the side surfaces of the lower layer wiring 71 to be approximately perpendicular to the array substrate 2 instead of taper-shaped, post-baking in the photolithography step in step S20 is performed under a condition by which end portions of the resist pattern are not tapered. Next, dry etching in the etching step in step S30 is performed under a condition by which polymer is not accumulated at side walls of the lower layer wiring 71. If post-baking and dry etching are performed under such conditions, the lower layer wiring 71 is not tapered on side surfaces, and the side surfaces become approximately perpendicular to the array substrate 2.

Furthermore, the upper layer wiring 72 is formed by using a wet etching method, and thus, its cross-sectional shape is approximately perpendicular to the array substrate 2, like the cross-sectional shape of the lower layer wiring 71. Note that, the structure of the first wiring 70 according to the present embodiment, and the method for manufacturing the same have been described. The structure of the second wiring, and the method for manufacturing the same are the same as those in the case of the first wiring 70, and description thereof is omitted.

The first wiring 70 of the present embodiment is not tapered on its side surfaces, and thus, the step coverage of a gate insulating film deposited to cover the first wiring 70 is not improved. However, as in the case of the first embodiment, the first wiring 70 is prevented from being disconnected at a part which is nearly disconnected due to repeated use by a user, and abnormal display of an image can be prevented. Also, because pattering of the lower layer wiring 71 and the upper layer wiring 72 is performed using the same photomask, the misregistration between the patterns of the lower layer wiring 71 and the upper layer wiring 72 can be made small. Moreover, if the misregistration between the patterns is made small, the upper layer wiring 72 covering the lower layer wiring 71 can be easily formed by simply reducing the amount of exposure at the time of patterning of the upper layer wiring 72.

Moreover, the first and second titanium layers 76, 78 included in the lower layer wiring 71 have high environmental resistance with respect to the phosphoric-nitric-acetic acid aqueous solution used for etching of the upper layer wiring 72, moisture entering from outside through the passivation film, and the like, and the aluminum layer 77 sandwiched between the first and second titanium layers 76, 78 can be sufficiently protected. Also, the molybdenum-niobium layer 79 forming the upper layer wiring 72 has high environment resistant with respect to moisture entering from outside, and the like, and is thus not easily corroded by moisture entering from outside. The reliability of the first wiring 70 can thus be maintained at a high level. Note that, these effects regarding the first wiring 70 are also true for the second wiring.

### 3. Third Embodiment

The configuration of a liquid crystal display device according to a third embodiment of the present invention, and the arrangement of wirings formed in the liquid crystal display device are the same as the configuration of the liquid crystal display device 1 shown in FIG. 2, and the arrangement of wirings shown in FIG. 3, respectively. Accordingly, a block diagram showing the configuration of the liquid crystal display device according to the present embodiment, a plan view showing the arrangement of wirings, and description thereof will be omitted.

A wiring structure of a first wiring 80 that is formed in the liquid crystal display device according to the present embodiment will be described in comparison to the wiring structure of the first wiring 40 according to the first embodiment. FIG. 12 is a cross-sectional diagram showing a cross-section of the first wiring 80 according to the present embodiment. As shown in FIG. 12, the structure of a lower layer wiring 81 of the first wiring 80 is the same as the structure of the lower layer wiring 41 shown in FIG. 4. However, an upper layer wiring 82 formed of a molybdenum-niobium layer 89 covers only the upper surface of the lower layer wiring 81 instead of the entire surface of the lower layer wiring 81, and does not cover the side surfaces of the lower layer wiring 81.

Next, a method for manufacturing the first wiring 80 of the present embodiment will be described in comparison with the first wiring 40 of the first embodiment. The flowchart as shown in FIG. 6, and the cross-sectional diagrams of respective manufacturing steps as shown in FIGS. 7(A) to 7(E) and FIGS. 8(F) to 8(J) are approximately the same for the present embodiment. However, the processing condition for the photolithography step in step S60 shown in FIG. 6 is partially different. In step S60, a resist pattern is formed at the time of patterning of the deposited molybdenum-niobium film, by using the same photomask as the photomask used for forming the lower layer wiring 81. At this time, unlike in the case of the first embodiment, exposure is performed with a greater amount of exposure than at the time of forming the resist pattern for the lower layer wiring 81. As a result, overexposure is performed with respect to light that is radiated on the molybdenum-niobium film, and the line width of the resist pattern is reduced, and the resist pattern is formed only on the upper surface of the lower layer wiring 81. If the molybdenum-niobium film is etched using this resist pattern as the mask, the upper layer wiring 82 is formed only on the upper surface of the lower layer wiring 81, and is not formed on the side surfaces of the lower layer wiring 81. Note that, the structure of the first wiring 80 according to the present embodiment, and the method for manufacturing the same have been described. The structure of the second wiring, and the method for manufacturing the same are the same as in the case of the first wiring 80, and description thereof is omitted.

According to the present embodiment, as in the case of the first embodiment, a case where an image is not normally displayed due to disconnection of the first wiring 80 at the time of use by a user can be prevented by increasing the reliability of the first wiring 80. Also, by using the same photomask in the photolithography steps for the lower layer wiring 81 and the upper layer wiring 82 forming the first wiring 80, the misregistration between the patterns of the lower layer wiring 81 and the upper layer wiring 82 can be made small. Moreover, by changing the amount of exposure, it is possible to form the upper layer wiring 82 only on the upper surface of the lower layer wiring 81. Furthermore, because the lower layer wiring 81 is tapered on both sides, the step coverage of an insulating film, such as a gate insulating film, formed to cover the first wiring 80 is improved, and step-cut is made less likely. The structure of the second wiring, and the method for manufacturing the same are the same as in the case of the first wiring 80, and description thereof is omitted.

Note that, because the side surfaces of the lower layer wiring 81 are not covered by the upper layer wiring 82, the side surfaces of an aluminum layer 87 included in the lower layer wiring 81 are corroded by the phosphoric-nitric-acetic acid aqueous solution at the time of wet etching for forming the upper layer wiring 82. However, even though the aluminum layer 87 is corroded, the corrosion resistance of first and second titanium layers 86, 88 having high conductivity is high, and the conductivity of the lower layer wiring 81 is not reduced so much as to affect the operation of the liquid crystal display device.

### 3.1 Example Modification

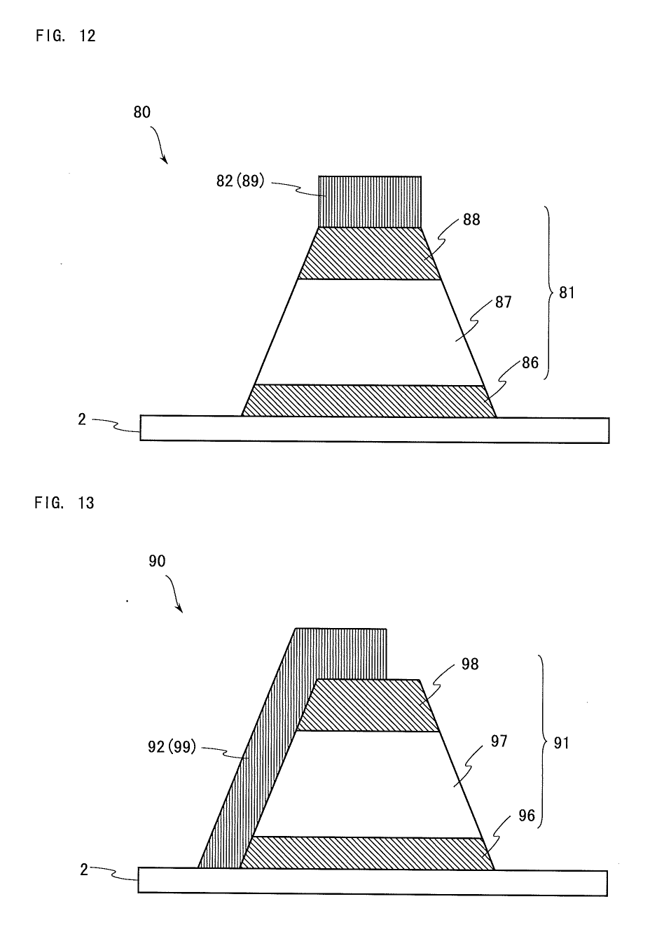

FIG. 13 is a diagram showing a cross-section of a first wiring 90, which is an example modification of the present embodiment. As shown in FIG. 13, the first wiring 90 of the present example modification also has a laminated structure in which a lower layer wiring 91 which is a laminated wiring having a three-layer structure as in the case of the first embodiment, and an upper layer wiring 92 formed of a molybdenum-niobium layer 99 are stacked. However, the upper layer wiring 92 is formed shifted in the wiring width direction with respect to the lower layer wiring 91. Thus, one side surface of the lower layer wiring 91 is covered by the upper layer wiring 92, but the other side surface is not covered by the upper layer wiring 92.

A method for manufacturing such a first wiring 90 may be achieved by simply changing the photolithography step in step S60 shown in FIG. 6 such that exposure is performed by shifting the photomask in the wiring width direction with respect to the pattern of the lower layer wiring 91.

The effects of the present example modification are the same as the effects of the third embodiment, and description thereof is omitted. Also, the structure of the second wiring, and the method for manufacturing the same are the same as in the case of the first wiring 90, and description thereof is omitted.

### 4. Others

In each of the embodiment described above, the first wiring is described as a wiring formed of a laminated metal layer where an aluminum layer is sandwiched between titanium layers on both sides, and the second wiring is described as a wiring including a single-layer metal layer formed of a molybdenum-niobium layer. However, the lower layer wiring and the upper layer wiring may be wirings formed of structures and metal layers as described below.

The lower layer wiring may be any one of a single-layer metal layer, a laminated metal layer having two layers, and a laminated metal layer having three layers. As the single-layer metal layer, any one of a titanium layer, a copper (Cu) layer, an aluminum layer, an aluminum alloy layer, a tungsten (W) layer, a chromium (Cr) layer, a tantalum (Ta) layer, and an aluminum-silicon (Al—Si) layer can be used, for example. If the lower layer wiring is formed of a single-layer metal layer as describe above, a wiring having a laminated structure which is not easily disconnected can be realized by a simple structure. Moreover, with such a structure, the manufacturing process of a wiring can be reduced, and the material cost can be suppressed, and thus, the manufacturing cost of a wiring can be reduced.

As the laminated metal layer having two layers, a laminated metal layer formed of any one of combinations: a titanium layer and an aluminum layer; a titanium layer and a copper layer; a titanium layer and an aluminum alloy layer; a titanium layer and a tungsten layer; a titanium layer and a chromium layer; a titanium layer and a tantalum layer; a copper layer and a tungsten layer; a copper layer and a chromium layer; and a copper layer and a tantalum layer can be used, where one of the combination is provided as a lower layer and the other is provided as an upper layer, for example. The same effects as in those of the single-layer metal layer can thereby be obtained.

As the laminated metal layer having three layers, a laminated metal layer having one of a copper layer, an aluminum alloy layer, a tungsten layer, a chromium layer, a tantalum layer, and an aluminum-silicon layer sandwiched between titanium layers, or a laminated metal layer having an aluminum layer sandwiched between a titanium nitride layer and a titanium layer can be used, for example, instead of the laminated metal layer described in each of the embodiments above which sandwiches an aluminum layer between titanium layers. With the laminated metal layer having three layers, the metal layer of the lower layer wiring is sandwiched between titanium layers or titanium nitride layers which are not easily etched at the time of etching of the upper layer wiring, and thus, the lower layer wiring is not easily corroded at the time of etching of the upper layer wiring. The reliability of the wiring can thus be increased. Note that, an aluminum alloy layer as described above includes an aluminum-nickel (Ni) based alloy layer such as aluminum-nickel-copper-lanthanum (La), for example.

Furthermore, with respect to each of the lower layer wirings, the upper layer wiring may be a single-layer metal layer formed of only the molybdenum-niobium layer or a single-layer metal layer made of only molybdenum (Mo).

In each of the embodiments described above, the wiring structure of a liquid crystal display device has been described, but the wiring structure of the present invention can also be applied to wirings of a display device such as an organic electro-luminescence (EL) display device.

### INDUSTRIAL APPLICABILITY

The present invention is applied to a display device such as a liquid crystal display device.

### DESCRIPTION OF REFERENCE CHARACTERS

1: LIQUID CRYSTAL DISPLAY DEVICE
2: ARRAY SUBSTRATE
4: DISPLAY UNIT
5: SCANNING SIGNAL LINE DRIVE CIRCUIT
6: DATA SIGNAL LINE DRIVE CIRCUIT
7: DISPLAY CONTROL CIRCUIT
21: GATE LEAD LINE
22: SOURCE LEAD LINE
23: POWER LINE
40, 70, 80, 90: FIRST WIRING
41, 71, 81, 91: LOWER LAYER WIRING
42, 72, 82, 92: UPPER LAYER WIRING
46, 76, 86, 96: FIRST TITANIUM LAYER
47, 77, 87, 97: ALUMINUM LAYER
48, 78, 88, 98: SECOND TITANIUM LAYER
49, 79, 89, 99: MOLYBDENUM-NIOBIUM LAYER
100: METAL FILM
101: RESIST PATTERN
102: PARTICLE
103: OPENING
104: WIRING
105: PORTION OF WIRING WHERE WIDTH IS NARROWED

1. A display device formed on an insulating substrate, the device comprising:
a display unit including a plurality of scanning signal lines formed on the insulating substrate, a plurality of data signal lines each intersecting with the plurality of scanning signal lines, and a plurality of pixel formation portions arranged in a matrix in correspondence with respective intersections of the scanning signal lines and the data signal lines;
a scanning signal line drive circuit configured to sequentially activate the scanning signal lines;
a data signal line drive circuit configured to apply a voltage according to image data to the data signal line; and
a plurality of types of wirings connected, respectively, to the scanning signal line drive circuit and the data signal line drive circuit,
wherein at least the scanning signal lines, the data signal lines, or the plurality of types of wirings are wirings having a laminated structure including a lower layer wiring and an upper layer wiring that is formed to cover at least a part of a surface of the lower layer wiring.

2. The display device according to claim 1, wherein the upper layer wiring is formed to cover an upper surface and both side surfaces of the lower layer wiring.

3. The display device according to claim 1, wherein the plurality of types of wirings include a gate lead line connected to the scanning signal line, a source lead line connected to the data signal line, and a power line connected to the scanning signal line, and are wirings formed in a same manufacturing step as the scanning signal line.

4. The display device according to claim 1, wherein the lower layer wiring is formed of any one of a titanium layer, a copper layer, an aluminum layer, an aluminum alloy layer, a tungsten layer, a chromium layer, and an aluminum-silicon layer, and the upper layer wiring is formed of one of a molybdenum-niobium layer and a molybdenum layer.

5. The display device according to claim 1, wherein the lower layer wiring is a laminated wiring formed of any one of combinations: a titanium layer and an aluminum layer; a titanium layer and a copper layer; a titanium layer and an aluminum alloy layer; a titanium layer and a tungsten layer; a titanium layer and a chromium layer; a titanium layer and a tantalum layer; a copper layer and a tungsten layer; a copper layer and a chromium layer; and a copper layer and a tantalum layer, where one of the combination is provided as a lower layer and the other is provided as an upper layer, and the upper layer wiring is formed of one of a molybdenum-niobium layer and a molybdenum layer.

6. The display device according to claim 1, wherein the lower layer wiring is a laminated wiring sandwiching any one of an aluminum layer, a copper layer, an aluminum alloy layer, a tungsten layer, a chromium layer, a tantalum layer, and an aluminum-silicon layer between titanium layers, or a laminated wiring sandwiching an aluminum layer between a titanium nitride layer and a titanium layer, and the upper layer wiring is formed of one of a molybdenum-niobium layer and a molybdenum layer.

7. A method for manufacturing a display device according to claim 1, the method comprising:
a first photolithography step of forming a first resist pattern for patterning the lower layer wiring;
a first etching step for forming the lower layer wiring with the first resist pattern as a mask;
a second photolithography step of forming a second resist pattern for patterning the upper layer wiring; and
a second etching step for forming the upper layer wiring with the second resist pattern as a mask,
wherein a photomask used in the second photolithography step is a same mask as a photomask that is used in the first photolithography step.

8. The method for manufacturing a display device according to claim 7, wherein an amount of exposure at a time of forming the second resist pattern is smaller than an amount of exposure at a time of forming the first resist pattern.

9. The method for manufacturing a display device according to claim 7, wherein the lower layer wiring is formed in the first etching step by a dry etching method, and the upper layer wiring is formed in the second etching step by a wet etching method using an etchant with a high selectivity of the upper layer wiring to the lower layer wiring.

10. The method for manufacturing a display device according to claim 9, wherein the etchant is a phosphoric-nitric-acetic acid aqueous solution.
